(19) United States
(12) Patent Application Publication
(10) Pub. No.: US 2025/0102628 A1
(43) Pub. Date: Mar. 27, 2025

(54) PHOTONIC CRYSTAL SURFACE-EMITTING LASER DIODES AND RELATED DEVICES FOR SELF-MIXING INTERFERENCE OR FREQUENCY MODULATED CONTINUOUS WAVE SENSING

(71) Applicant: Apple Inc., Cupertino, CA (US)

(72) Inventors: Fei Tan, Sunnyvale, CA (US); Pengfei Qiao, El Cerrito, CA (US); Alexander Hein, Luebeck (DE); Chin Han Lin, Santa Clara, CA (US); Tong Chen, Fremont, CA (US); Takashi Hosoda, Sunnyvale, CA (US); Arnaud Laflaquiere, Paris (FR)

(21) Appl. No.: 18/763,961

(22) Filed: Jul. 3, 2024

Related U.S. Application Data
(60) Provisional application No. 63/540,844, filed on Sep. 27, 2023.

(51) Int. Cl. G01S 7/481; G01S 17/89; H01S 5/11; H01S 5/183; H01S 5/34; H01S 5/42

(52) U.S. Cl. CPC G01S 7/4811; G01S 17/89; H01S 5/11; H01S 5/18305; H01S 5/18361; H01S 5/3416; H01S 5/423

(57) ABSTRACT

Disclosed herein are self-mixing interference (SMI) sensors, frequency modulated continuous wave (FMCW) sensors, and electronic devices that include SMI and FMCW sensors. Both types of sensors include a photonic crystal surface-emitting laser diode. The SMI sensors include a photonic crystal surface-emitting laser diode configured to undergo SMI between a primary emitted light from the photonic crystal surface-emitting laser diode and reflections thereof from an object. The SMI sensor includes a photodetector configured to receive a secondary light emission from the photonic crystal surface-emitting laser diode and detect a parameter related to the SMI, from which distance or motion to the object may be inferred. The FMCW sensors include a photonic crystal surface-emitting laser diode configured to emit a primary light emission toward the object and a secondary light emission toward a light beam combiner. The light beam combiner also receives reflections from the object and detects distances and/or motion of the object based on the frequency modulations of the two light beams.

### CROSS-REFERENCE TO RELATED APPLICATION (2)

This application is a nonprovisional and claims the benefit under 35 U.S.C. § 1.119(e) of U.S. Provisional Patent Application No. 63/540,844, filed Sep. 27, 2023, the contents of which are incorporated herein by reference as if fully disclosed herein.

### FIELD

The present disclosure generally relates to laser diodes, such as photonic crystal surface-emitting laser diodes, and associated photodetectors. Examples of photonic crystal surface-emitting laser diodes include any laser diode having a photonic crystal layer, such as photonic cavity surface-emitting laser diodes (PCSELs) and topological cavity surface-emitting laser diodes (TCSELs). For the remainder of this description, a reference to a PCSEL is understood to be a reference to any type of photonic crystal surface-emitting laser diode (e.g., a PCSEL or a TCSEL).

The present disclosure also relates to sensor devices that include such PCSELs. The laser diodes and associated photodetectors may be configured so that self-mixing interference (SMI) is used for sensing or detection of objects. Additionally and/or alternatively, the laser diodes and associated photodetectors may be configured so that frequency modulated continuous wave (FMCW) sensing is used for sensing or detection of objects.

The PCSELs or other laser diodes may be used in sensor devices such as digital cameras or light detection and ranging (LIDAR) devices, among others. The devices may include arrays of PCSELs or other laser diodes and associated photodetectors.

### BACKGROUND

Electronic devices with light transmitting and sensing systems are commonplace in today's society. Example electronic devices include cell phones and computers with cameras, stand-alone cameras, LIDAR systems, facial recognition security systems, and the like. Some of these electronic devices include laser diodes, such as vertical surface-emitting laser diodes (VCSELs), edge-emitting laser diodes (EELs), vertical exterior cavity emitting laser diodes (VECSELs), or other types of laser diodes. The laser diodes may be provided in an array, such as on a semiconductor chip. An electronic device may cause such component laser diodes to emit light from the electronic device toward an object in an exterior environment of the electronic device. The emitted light may be pulsed or continuous, and may be provided in flood, spot, or patterned form.

An electronic device may also include one or more photodetectors (PDs) that are configured to receive reflections of the emitted laser light from the object. Types of photodetectors may be complimentary metal-oxide semiconductor (CMOS) PDs, single photon avalanche diodes (SPADs), resonant cavity photodetectors (RCPDs), or other types of photodetectors. In some embodiments, an array of PDs may be provided separately from an array of laser diodes. Alternatively, an array of PDs may be integrated with an array of laser diodes (e.g., interspersed with or stacked with an array of laser diodes).

An electronic device may estimate distances to an object based on received reflections of emitted laser light, by any of various methods including but not limited to time-of-flight (TOF) sensing, SMI sensing, FMCW sensing, or other sensing methods.

Based on an estimated distance (or distances) to an object (or objects), an electronic device may form a depth map or image of the object, which may then be used for autofocusing, facial recognition, motion detection, surface mapping, hazard avoidance, or other purposes.

### SUMMARY

This summary is provided to introduce a selection of concepts in a simplified form that are further described below in the Detailed Description section. This summary is not intended to identify key features or essential features of the claimed subject matter, nor is it intended to be used as an aid in determining the scope of the claimed subject matter.

Disclosed herein are electronic devices, systems, and various components thereof that emit light and detect properties of objects in an environment based on received reflections of the emitted light. The electronic devices, systems, and components may include light emitting laser diodes and photodetectors. Examples of such electronic devices and systems include LIDAR systems and cameras in smart phones, among others.

More specifically, a first family of embodiments discloses a self-mixing interferometry (SMI) sensor that includes a photonic crystal light emitting laser diode disposed on a substrate and an associated photodetector. The photonic crystal light emitting laser diode is configured to make a primary light emission through the substrate toward an object in an environment of the SMI sensor. The photonic crystal light emitting laser diode includes a photonic crystal layer, an active region, and a first and second semiconductor cladding layer. The active region is disposed between the photonic crystal layer and the substrate with a primary emission side through which the primary light emission occurs, the first semiconductor cladding layer is disposed on the primary emission side of the active region and disposed between the active region and the substrate, and the second semiconductor cladding layer is disposed on a secondary light emission side of the active region, with the secondary light emission side opposite from the primary emission side, the photonic crystal layer disposed between the second semiconductor cladding layer and the active region. The SMI sensor also includes a distributed Bragg reflector (DBR) disposed on the second semiconductor cladding layer such that the second semiconductor cladding layer is disposed between the DBR and the photonic crystal layer. The associated photodetector is positioned proximate to the DBR and configured to receive a secondary light emission emitted from the photonic crystal surface-emitting laser diode through the second semiconductor cladding layer and the DBR, with the photodetector configured to produce a measurable electrical parameter related to self-mixing of light within the photonic crystal surface-emitting laser diode. The photonic crystal layer may have a planar pattern of voids.

In some embodiments, the DBR of the SMI sensor may be a first DBR, and the photodetector includes a photodetector absorption layer adjacent to the first DBR and opposite to the second semiconductor cladding layer, and a second DBR adjacent to the photodetector absorption layer and opposite to the first DBR.

In some embodiments, the photonic crystal surface-emitting laser diode and the photodetector comprise epitaxial layers on the substrate and the measurable electrical parameter related to the self-mixing is a photocurrent of the photodetector.

In some embodiments the photodetector is spaced apart from the DBR, and the photodetector is electrically connected to the DBR by metallic links between at least a first electrode on the DBR and at least a second electrode on the photodetector.

A second family of embodiments discloses a frequency modulated, continuous wave (FMCW) sensor that includes: a semiconductor current distribution layer, a photonic crystal surface-emitting laser diode disposed on the semiconductor current distribution layer and configured to make a primary light emission through the semiconductor current distribution layer, a distributed Bragg reflector (DBR), a semiconductor substrate layer, a light beam combiner, and an optoelectronic circuit. The a photonic crystal surface-emitting laser diode includes: a photonic crystal layer, an active region disposed between the photonic crystal layer and the semiconductor current distribution layer, having a primary emission side through which the primary light emission occurs, a first semiconductor cladding layer disposed on the primary emission side of the active region and disposed between the active region and the semiconductor current distribution layer, and second semiconductor cladding layer disposed on a secondary light emission side of the active region, the secondary light emission side opposite from the primary emission side, the photonic crystal layer disposed between the second semiconductor cladding layer and the active region. The DBR is disposed on the second semiconductor cladding layer such that the second semiconductor cladding layer is disposed between the DBR and the photonic crystal layer. The semiconductor substrate layer is disposed adjacent to the DBR opposite to the second semiconductor cladding layer. The light beam combiner is positioned across a gap from the semiconductor substrate layer of the photonic crystal surface-emitting laser diode PCSEL and configured to produce an FMCW optical output by combining a reflection of the primary light emission emitted from the primary emission side of the active region and a secondary light emission emitted from the secondary light emission side of the active region, the secondary light emission emitted through the semiconductor substrate layer. The optoelectronic circuit is configured to receive the FMCW optical output and produce a measurable electrical parameter related to a modulation of the FMCW optical output.

In some embodiments, the semiconductor current distribution layer has n-type doping, the first semiconductor cladding layer has n-type doping, the second semiconductor cladding layer has p-type doping, the DBR has p-type doping, and the semiconductor substrate layer has n-type doping and is one of gallium arsenide (GaAs), indium phosphorus (InP) or another semiconductor, such as a III-V semiconductor. The FMCW sensor may also comprise a tunnel junction. The photonic crystal surface-emitting laser diode FMCW sensor may include at least one on-chip lens positioned on the semiconductor substrate layer and configured to direct the secondary light emission to the light beam combiner.

The light beam combiner of the FMCW sensor may also include a first metasurface configured to combine the reflection of the primary light emission with secondary light emission and produce a first combined output and a second metasurface configured to combine the reflection of the primary light emission with secondary light emission and produce a second combined output. The optoelectronic circuit may include a first photodetector positioned to receive the first combined output, a second photodetector positioned to receive the second combined output light, and an amplifier configured to receive both an electrical output of the first photodetector and an electrical output of the second photodetector.

A third family of embodiments discloses an electronic device that includes: an array of photonic crystal surface-emitting laser diodes, each photonic crystal surface-emitting laser diode operable to emit a primary light emission from the photonic crystal surface-emitting laser diodes through a light emission surface of the electronic device toward one or more objects exterior to the electronic device, an array of photodetectors configured to receive at least a secondary light emission emitted from the photonic crystal surface-emitting laser diodes of the array of photonic crystal surface-emitting laser diodes toward the array of photodetectors; and electronic circuitry configured to receive measurable output signals from photodetectors of the array of photodetectors. Each photonic crystal surface-emitting laser diode of the array of photonic crystal surface-emitting laser diodes includes: an n-doped current distribution layer proximate to the light emission surface of the electronic device through which the primary light emission is emitted from the electronic device; an n-type cladding layer adjacent to the n-doped current distribution layer and opposite to the light emission surface of the electronic device; an active region adjacent to the n-type cladding layer and opposite to the semiconductor substrate layer; a photonic crystal layer adjacent to the active region and opposite to the n-type cladding layer; a p-type cladding layer adjacent to the photonic crystal layer and opposite to the active region; and a p-type distributed Bragg reflector (DBR) layer adjacent to the p-type cladding layer and opposite to the photonic crystal layer.

In some embodiments, the photonic crystal surface-emitting laser diodes of the array of photonic crystal surface-emitting laser diodes are individually addressable by the electronic circuitry.

In some embodiments the electronic circuitry of the electronic device is operable to produce a depth map of the one or more objects exterior to the electronic device using the measurable output signals from the photodetectors of the array of photodetectors.

In some embodiments, the photodetectors of the array of photodetectors include a photodetector absorption layer, the photodetectors of the array of photodetectors produce output signals related to self-mixing interference of the secondary light emission with reflections of the primary light emission from the one or more objects exterior to the electronic device, and the output signals related to the self-mixing interference are included in the measurable output signals used by the electronic device to produce the depth map.

In some embodiments, the photodetectors of the array of photodetectors include a pair of separate and balanced semiconductor photodetectors with respective metasurfaces, the metasurfaces are configured to combine the secondary light emission with reflections of the primary light emission from the one or more objects exterior to the electronic device, and the pair of separated and balanced semiconductor photodetectors produce respective output photocurrents related to frequency modulation between the combined primary light emission and the secondary light emission.

### BRIEF DESCRIPTION OF THE DRAWINGS

The disclosure will be readily understood by the following detailed description in conjunction with the accompanying drawings, wherein like reference numerals designate like structural elements.

FIGS. 1A and 1B show an example of a device that may include one or more of an image sensor, camera, light sensor, or depth/range sensor that may make use of the embodiments disclosed herein.

FIG. 1C is a simplified block diagram of a LIDAR system that may make use of the embodiments disclosed herein.

FIG. 2A shows an exploded view of certain components of a PCSEL, according to an embodiment.

FIG. 2B shows a top view of a photonic crystal layer of a PCSEL, according to an embodiment.

FIG. 3 shows a cross-sectional view of a PCSEL joined with a PD, according to an embodiment.

FIG. 4 shows a cross-sectional view of a PCSEL separated by a gap from a PD, according to an embodiment.

FIG. 5A shows a cross-sectional view of a PCSEL and an associated light combination component, according to an embodiment.

FIG. 5B illustrates a doping configuration of a tunnel junction of the PCSEL of FIG. 5A, according to an embodiment.

FIG. 5C illustrates electrical components associated with the light combination component of FIG. 5A, according to an embodiment.

FIG. 5D shows a specific embodiment of the light combination component of FIG. 5A, according to an embodiment.

FIG. 6 illustrates a block diagram of an electronic device that may include one or more of the embodiments described herein.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following description is not intended to limit the embodiments to one preferred embodiment. To the contrary, it is intended to cover alternatives, modifications, and equivalents as can be included within the spirit and scope of the described embodiments as defined by the appended claims.

Further, although specific electronic devices are shown in the figures and described below, the SMI sensors and FMCW sensors, and the PCSEL structures described herein, may be used with various electronic devices including, but not limited to, mobile phones, personal digital assistants, a time keeping device, a health monitoring device, a wearable electronic device, an input device (e.g., a stylus), a desktop computer, electronic glasses, and so on. Other examples and implementations are within the scope and spirit of the disclosure and appended claims. Although various electronic devices are mentioned, the of the present disclosure may also be used in conjunction with other products and combined with various materials.

Directional terminology, such as “top”, “bottom”, “upper”, “lower”, “front”, “back”, “over”, “under”, “above”, “below”, “left”, “right”, etc. is used with reference to the orientation of some of the components in some of the figures described below. Because components in various embodiments can be positioned in a number of different orientations, directional terminology is used for purposes of illustration and is not always limiting. The directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

The embodiments described herein are directed to electronic devices or systems that include SMI sensors or FMCW sensors. The SMI and FMCW sensors include one or more PCSEL structures and associated PDs. Examples of such devices or systems that use such SMI or FMCW sensors include LIDAR systems, object detection and mapping systems on self-driving automobiles, cameras on computers or cell phones, and other electronic devices.

The SMI and FMCW sensors described use emitted laser light, combined with reflections thereof, to detect or sense an object, or its properties, exterior to the sensor. The sensors may be configured to detect a distance or range to one or more objects exterior to the device and/or a motion or speed of the object. The electronic devices may include an array of such SMI and/or FMCW sensors.

The sensors described herein may include one or more PCSELs. (Hereinafter, the acronyms for the various mentioned types of laser diodes will presume the word “diode”). The PCSELs may be structured to generate and emit laser light, called a primary light emission, in a first direction toward the object, and also emit the generated laser light, called a secondary light emission, in a direction opposite (or different) from the primary light emission. Reflections of the primary light emission from the object may be received in the sensor and may be combined either with the primary light emission or the secondary light emission. Properties of the combined light (wavelength, phase, modulation, frequency, etc.) may produce signals in components of the sensor that the sensor or device may then use to estimate distance or motion of the object or objects. The PCSELs described herein may include a photonic crystal layer, having a patterned photonic crystal structure. Such patterned photonic crystal structures include (for photonic crystal layers with a thickness much less than lateral dimensions) a planar pattern in the lateral dimensions of cavities, or of two or more materials of different refractive indices. A patterned photonic crystal structure may also have a three-dimensional pattern of materials of different refractive indices.

A first family and a second family of embodiments make use of SMI that occurs within a PCSEL's lasing cavity between the primary light emission and reflections thereof that are received from the object back into the PCSEL's lasing cavity. The SMI induces changes in a property of the emitted laser light. The extent of the changes induced by the SMI may correlate to a distance to the object. The alteration from an unmixed emitted light to the SMI emitted light can produce corresponding changes in an electrical or other parameter of the PCSEL, such as changes in junction voltage, diode current, or another parameter, which may be measurable by electrical components associated with the PCSEL. Additionally or alternatively, a secondary light emission from the PCSEL may be the SMI emitted light directed to a photodetector, which may have measurable parameters correlated to the changes induced by the SMI.

In the first family of embodiments, the PCSEL is joined to a photodetector, such as a photodiode, positioned on a side opposite the side from which the primary light emission is emitted. In some embodiments, the photodiode detector may be structured as a resonant cavity photodiode (RCPD). In these embodiments, the PCSEL further may emit the secondary light emission toward the RCPD, which may have a measurable parameter that correlates with the SMI. In the first family of embodiments, the RCPD and the PCSEL may be formed, such as by epitaxial deposition or other technologies, on a single semiconductor substrate.

A second family of embodiments also makes use of the SMI that occurs within a PCSEL's lasing cavity between the primary emitted light and reflections that are received from the object back into the PCSEL's lasing cavity. In the second family of embodiments, the PCSEL structure may include a distributed Bragg reflector (DBR) joined to the photonic crystal layer. A DBR is a structure formed from multiple alternating layers of materials with different refractive indexes, which can provide full or partial reflectivity. In this family of embodiments, a photodetector may be separated from the PCSEL and DBR structure and may receive the secondary light emission that has been altered by the SMI. The photodetector in this family of embodiments may be a photodiode, an RCPD, a CMOS photodetector, or another photodetector.

A third family of embodiments makes use of FMCW mixing of the reflections of the primary light emission with a secondary light emission from the PCSEL. The secondary light emission may be directed in opposite direction from the primary light emission, toward a light beam combiner that is separate from the PCSEL structure. In these embodiments the PCSEL may include a DBR joined to the PCSEL. The secondary light emission from the PCSEL may be modulated in wavelength, such as by varying a voltage applied to the PCSEL, and combined at the light beam combiner with the reflections of the primary light emission to produce a frequency modulated light input to the PD.

In some embodiments of the light beam combiner, there are two separated, balanced PDs that each include a metasurface that receives and combines both the secondary light emission and the reflections of the primary light emission. Each PD's output may be inputs to a differential amplifier and subsequent signal processing components.

In additional and/or alternative embodiments, a light beam combiner may combine both the secondary light emission and the reflections of the primary light emission into a combined beam, which combined beam may be input into a fiber optic cable or waveguide. A beam splitter thereafter may provide an equal (50/50 split) of the combined beam into a balanced photodetector that provides the frequency modulated, continuous wave detection, followed by subsequent signal processing.

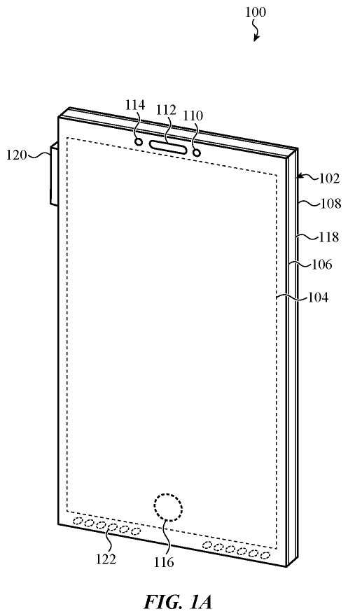

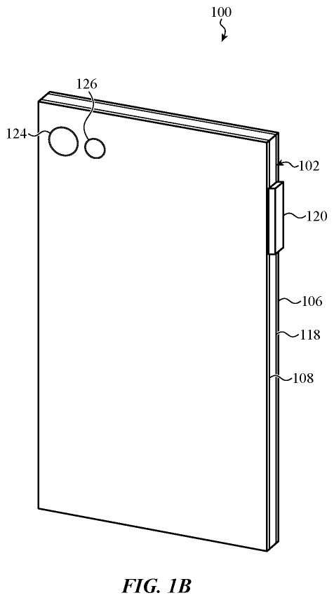

These and other embodiments are discussed below with reference to FIGS. 1A-6. However, those skilled in the art will readily appreciate that the detailed description given herein with respect to these Figures is for explanatory purposes only and should not be construed as limiting.

FIGS. 1A and 1B show an example of a device 100 that may include an image sensor or depth sensor. The device's dimensions and form factor, including the ratio of the length of its long sides to the length of its short sides, suggest that the device 100 is a mobile phone (e.g., a smartphone). However, the device's dimensions and form factor are arbitrarily chosen, and the device 100 could alternatively be any portable electronic device including, for example a mobile phone, tablet computer, portable computer, portable music player, wearable device (e.g., an electronic watch, health monitoring device, or fitness tracking device), augmented reality (AR) device, virtual reality (VR) device, mixed reality (MR) device, gaming device, portable terminal, digital single-lens reflex (DSLR) camera, video camera, vehicle navigation system, robot navigation system, or other portable or mobile device. The device 100 could also be a device that is semi-permanently located (or installed) at a single location. FIG. 1A shows a front isometric view of the device 100, and FIG. 1B shows a rear isometric view of the device 100. The device 100 may include a housing 102 that at least partially surrounds a display 104. The housing 102 may include or support a front cover 106 or a rear cover 108. The front cover 106 may be positioned over the display 104, and may provide a window through which the display 104 may be viewed. In some embodiments, the display 104 may be attached to (or abut) the housing 102 and/or the front cover 106. In alternative embodiments of the device 100, the display 104 may not be included and/or the housing 102 may have an alternative configuration.

The display 104 may include one or more light-emitting elements, and in some cases may be a light-emitting diode (LED) display, an organic LED (OLED) display, a liquid crystal display (LCD), an electroluminescent (EL) display, or another type of display. In some embodiments, the display 104 may include, or be associated with, one or more touch and/or force sensors that are configured to detect a touch and/or a force applied to a surface of the front cover 106.

The various components of the housing 102 may be formed from the same or different materials. For example, a sidewall 118 of the housing 102 may be formed using one or more metals (e.g., stainless steel), polymers (e.g., plastics), ceramics, or composites (e.g., carbon fiber). In some cases, the sidewall 118 may be a multi-segment sidewall including a set of antennas. The antennas may form structural components of the sidewall 118. The antennas may be structurally coupled (to one another or to other components) and electrically isolated (from each other or from other components) by one or more non-conductive segments of the sidewall 118. The front cover 106 may be formed, for example, using one or more of glass, a crystal (e.g., sapphire), or a transparent polymer (e.g., plastic) that enables a user to view the display 104 through the front cover 106. In some cases, a portion of the front cover 106 (e.g., a perimeter portion of the front cover 106) may be coated with an opaque ink to obscure components included within the housing 102. The rear cover 108 may be formed using the same material(s) that are used to form the sidewall 118 or the front cover 106. In some cases, the rear cover 108 may be part of a monolithic element that also forms the sidewall 118 (or in cases where the sidewall 118 is a multi-segment sidewall, those portions of the sidewall 118 that are conductive or non-conductive). In still other embodiments, all of the exterior components of the housing 102 may be formed from a transparent material, and components within the device 100 may or may not be obscured by an opaque ink or opaque structure within the housing 102.

The front cover 106 may be mounted to the sidewall 118 to cover an opening defined by the sidewall 118 (i.e., an opening into an interior volume in which various electronic components of the device 100, including the display 104, may be positioned). The front cover 106 may be mounted to the sidewall 118 using fasteners, adhesives, seals, gaskets, or other components.

A display stack or device stack (hereafter referred to as a “stack”) including the display 104 may be attached (or abutted) to an interior surface of the front cover 106 and extend into the interior volume of the device 100. In some cases, the stack may include a touch sensor (e.g., a grid of capacitive, resistive, strain-based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 106 (e.g., to a display surface of the device 100).

In some cases, a force sensor (or part of a force sensor system) may be positioned within the interior volume above, below, and/or to the side of the display 104 (and in some cases within the device stack). The force sensor (or force sensor system) may be triggered in response to the touch sensor detecting one or more touches on the front cover 106 (or a location or locations of one or more touches on the front cover 106), and may determine an amount of force associated with each touch, or an amount of force associated with a collection of touches as a whole. In some embodiments, the force sensor (or force sensor system) may be used to determine a location of a touch, or a location of a touch in combination with an amount of force of the touch. In these latter embodiments, the device 100 may not include a separate touch sensor.

As shown primarily in FIG. 1A, the device 100 may include various other components. For example, the front of the device 100 may include one or more front-facing cameras 110 (including one or more image sensors or depth sensors, which in some cases may include one or more of the PCSELs described herein), speakers 112, microphones, or other components 114 (e.g., audio, imaging, and/or sensing components) that are configured to transmit or receive signals to/from the device 100. In some cases, a front-facing camera 110, alone or in combination with other sensors, may be configured to operate as a bio-authentication or facial recognition sensor. In some embodiments, a flash or electromagnetic radiation source (e.g., a visible or IR light source) may be positioned near the front-facing camera. In some cases, the front-facing camera 110 may be positioned behind the display 104 and receive electromagnetic radiation (e.g., light) through the display 104. In some cases, a depth sensor may be used to determine a distance to a user or generate a depth map of the user's face, or determine a distance or proximity to an object, or generate a depth map of the object or a FoV that includes the object. The device 100 may also include various input devices, including a mechanical or virtual button 116, which may be accessible from the front surface (or display surface) of the device 100.

The device 100 may also include buttons or other input devices positioned along the sidewall 118 and/or on a rear surface of the device 100. For example, a volume button or multipurpose button 120 may be positioned along the sidewall 118, and in some cases may extend through an aperture in the sidewall 118. The sidewall 118 may include one or more ports 122 that allow air, but not liquids, to flow into and out of the device 100. In some embodiments, one or more sensors may be positioned in or near the port(s) 122. For example, an ambient pressure sensor, ambient temperature sensor, internal/external differential pressure sensor, gas sensor, particulate matter concentration sensor, or air quality sensor may be positioned in or near a port 122.

In some embodiments, the rear surface of the device 100 may include a rear-facing camera 124 that includes one or more image sensors or depth sensors (see FIG. 1B), which in some cases may include one or more of the PCSELs described herein. A flash or electromagnetic radiation source 126 (e.g., a visible or IR light source) may also be positioned on the rear of the device 100 (e.g., near the rear-facing camera). In some cases, the rear surface of the device 100 may include multiple rear-facing cameras.

FIG. 1C is a simplified block diagram 130 of a LIDAR 132, which may include one or more of the various PCSELs disclosed herein. The LIDAR 132 may be used to detect distances to objects in an exterior environment, such as a tree 136a or a building 136b. The LIDAR 132 may use the detected distances to form a depth map or other image or images of the exterior environment. The LIDAR 132 may be handheld, mounted to a stationary object, or carried by a moving vehicle or airplane.

The LIDAR 132 may emit light directionally toward objects. In the particular case shown in FIG. 1C, the LIDAR 132 may emit sequentially within a first plane multiple light pulses 134a, followed by sequentially emitting within a second plane a second set of light pulses 134b. Though just two planes are shown swept with the light pulses 134a and 134b, the LIDAR 132 may emit light pulses across more planes. The light pulses may be laser pulses, such as may be emitted from one or more laser diodes within the LIDAR 132. The plane of an emitted laser pulse and the direction within the plane is controlled by mechanisms within the LIDAR 132, such as steerable optics, or by sequential emission of the laser pulses from an array of laser diodes in which the laser diodes are aimed at different directions to allow sweeping, both vertically and horizontally, of the exterior environment.

The LIDAR 132 may receive reflections 138a-d of the emitted light pulses, such as by one or more photodetectors, which may be in array. The photodetectors may be implemented in one or more of various technologies, such as resonant cavity photodiodes, single photon avalanche diodes, CMOS photodetectors, or another technology.

The LIDAR 132 may use time-of-flight measurements between emission of a light pulse and reception of a reflection thereof to estimate a distance to a part of an object along the direction of the emitted light pulse. Such directional distance estimates over the entirety of emitted light pulses may then be combined to detect objects, produce a depth map, or produce other types of information of the exterior environment of the LIDAR 132.

Alternatively, the laser diodes of the LIDAR 132 may be configured to undergo SMI with reflections of their emitted light. In SMI, the reflections of the emitted laser light are received back into the resonant cavity of the laser diode, causing alteration of the emitted light, such as a frequency, with such an alteration in the light altering a measurable parameter of either the laser diode, such as forward bias current, or of a PD associated with the laser diode.

FIGS. 1A-C describe various examples of electronic devices that make use of emitted light and received reflections for sensing an exterior environment and objects therein. However, one of ordinary skill in the art will recognize that other types and categories of electronic devices may also make use of emitted light and received reflections for sensing, and that the embodiments disclosed herein are not limited to any particular type or category of electronic device.

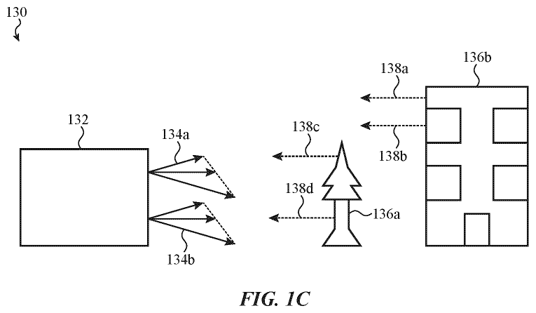

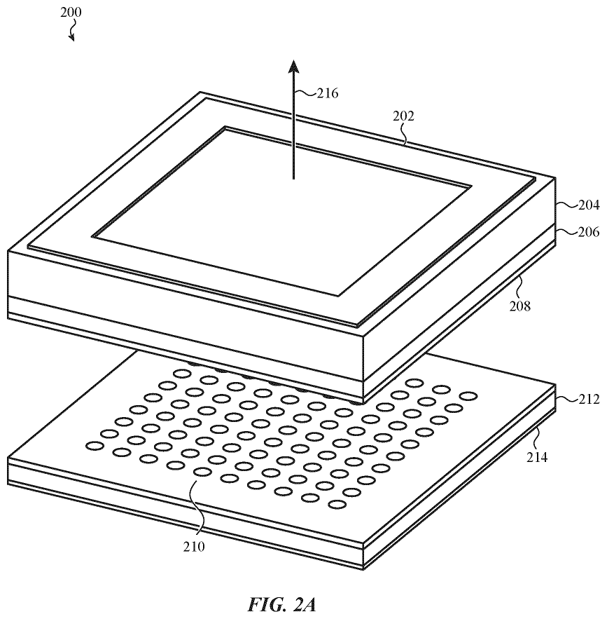

FIG. 2A shows an exploded view of certain various layers that may be present in or with a PCSEL 200. As described in the embodiments below, the PCSEL 200 may be part of an SMI sensor, an FMCW sensor, or another electronic device. In the following descriptions, the directional statements are made with respect to the orientation shown in FIG. 2A. The PCSEL 200 is configured to emit a laser light, (also referred to as the “primary light emission”) 216 vertically upwards. The PCSEL 200 is formed with a substrate layer (or just “substrate”) 204, which in some embodiments may be an n-type doped (or just “n-type”) semiconductor, such as a silicon (Si), gallium arsenide (GaAs), indium phosphide (InP), or other III-V semiconductor. The substrate 204 may be formed above a first semiconductor cladding layer 206, for which, in some embodiments, the constituent semiconductor may be Si, GaAs, InP, or other III-V semiconductor. In embodiments in which the substrate 204 is n-type doped, the first semiconductor cladding layer 206 may be n-type doped, so that together they form at least part of a cathode region of a diode structure.

The PCSEL 200 includes an active region 208, which may include quantum wells, and provide laser light amplification. Below the active region 208 is a photonic crystal layer 210 that, in some embodiments, includes a planar array having a photonic crystal structure, as described below in relation to FIG. 2B. The photonic crystal layer 210 may be formed as a layer of semiconductor material, such as Si, GaAs, InP, or other III-IV semiconductor. The photonic crystal layer 210 may be formed with voids. As known to one skilled in the art, the active region 208 may be separated from the photonic crystal layer 210 by a thin electron blocking layer (not shown).

Beneath the photonic crystal layer 210 is a second semiconductor cladding layer 212, which is p-type doped to form the anode section of the diode structure of the PCSEL 200. The constituent semiconductor of the second semiconductor cladding layer 212 may be Si, GaAs, InP, or another III-V semiconductor.

In the embodiment shown in FIG. 2A, a first electrode 202 is formed on the top side of the substrate 204. The first electrode 202 may be formed around the edge of the substrate 204 to provide an increase in surface area for the primary light emission 216 of the PCSEL 200. A second electrode 214 is formed on the side of the second semiconductor cladding layer 212 opposite from the photonic crystal layer 210. The first and second electrodes 202 and 214 may be metal, such as gold, or another conductive material. Though shown as a rectangular configuration, the first electrode 202, and the other described components of the PCSEL 200 itself, may be formed with another configuration, such as in a pattern of cylindrical layers.

In addition to the primary light emission 216, the PCSEL 200 may also be operable to emit light generated in the active region as a secondary light emission (not shown) vertically downward, opposite to the direction of the primary light emission 216, through the photonic crystal layer 210 and the second semiconductor cladding layer 212. As described in embodiments below, when used as a component in an SMI sensor or FMCW sensor, the primary light emission 216 may be directed exterior to the sensor, with the secondary light emission directed toward a photodetector.

FIG. 2B shows a top view of a section of a photonic crystal layer 220. The photonic crystal layer 220 has a three-dimensional rectangular pattern of voids or holes, illustrated as 222a-c in a first row and 224a-c in a second row, in a semiconductor base. Though only three voids in each of two rows is shown, one skilled in the art will recognize that various embodiments of the photonic crystal layer 220, can have other numbers of rows, with various numbers of voids in each row. The voids 222a-c and 224a-c shown have an approximately trapezoidal shape, though this is not required; in other embodiments the voids may have a rectangular, triangular, circular, or other shape. In some embodiments, the inter-void separation a may be on the order of 0.5 μm, with the width or length of the photonic crystal layer on the order of 400 μm. In some embodiments, the pattern of voids may be arranged in a pattern other than rectangular.

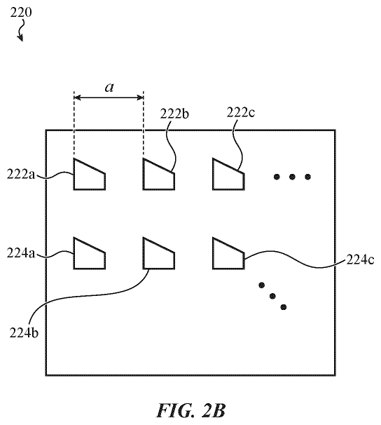

FIG. 3 is a cross-sectional view of a first embodiment of a SMI sensor 300. The SMI sensor 300 includes at least a PCSEL section (or just “PCSEL”) and an integrated photodetector section. The SMI sensor 300 includes the substrate 302 onto which components of the PCSEL and the integrated photodetector section are formed in layers. The substrate 302 may be a semiconductor such as Si, GaAs, InP, or another III-V semiconductor. The components of the PCSEL of the SMI sensor 300 include the first semiconductor cladding layer 304, the active region 306, the photonic crystal layer 308, and the second semiconductor cladding layer 310. The photodetector components of the SMI sensor 300 include a first DBR 312 and a second DBR 316 on opposite sides of a photodetector absorption layer 314. The first DBR 312 is connected to the second semiconductor cladding layer 310.

The first semiconductor cladding layer 304, the active region 306, the photonic crystal layer 308, the second semiconductor cladding layer 310, the first DBR 312, photodetector absorption layer 314, and second DBR 316 may be sequentially formed on the substrate 302 by any of various semiconductor fabrication techniques, such as epitaxial deposition.

The SMI sensor 300 may have one or more top electrodes 311a-b formed on the primary light emission side of the substrate 302, which is the side of the substrate 302 through which a primary light emission 320 is emitted. In the orientation of FIG. 3, the primary light emission side is the top of substrate 302. Though shown as two sections, the top electrodes 311a-b may be connected, such as shown for the first electrode 202 of FIG. 2A. The SMI sensor 300 may also have one or more intermediate electrodes 313a-b, which may be connected, such as in a ring around the second semiconductor cladding layer 310. The SMI sensor 300 may also include one or more base electrodes 319 on the side of the second DBR 316 that is opposite from the photodetector absorption layer 314.

The photodetector absorption layer 314 may be formed with single or multiple absorption layers (such as with InGaAs, GaAs, etc.) or with single or multiple quantum well structures (such as InGaAs/GaAs, InGaAs/GaAsP, and the like).

In some embodiments, the substrate 302 and the first semiconductor cladding layer 304 have n-type doping and form a cathode section of the PCSEL. In such embodiments, the second semiconductor cladding layer 310 is formed with p-type doping and forms an anode section. In the integrated photodetector section of the SMI sensor 300, in such embodiments, the first DBR 312 may be n-type doped, with the second DBR 316 having p-type doping. The integrated photodetector section thus has a diode structure as well.

When a higher voltage is applied to the intermediate electrodes 313a-b relative to a lower voltage applied to the top electrodes 311a-b, charge carriers are injected into the PCSEL and lasing from the active region 306 may be induced, causing the primary light emission 320 to pass through the first semiconductor cladding layer 304 and the substrate 302 and be emitted from the SMI sensor 300 toward a object 324 in the exterior environment of the SMI sensor 300. Under these applied voltages, if additionally a lower voltage is applied at the base electrode 319 than at the intermediate electrodes 313a-b, the photodetector section is electrically a reverse-biased diode, and the photodetector absorption layer 314 may operate as a resonant cavity.

The active region 306 may emit not only the primary light emission 320, but also a secondary light emission through the photonic crystal layer 308 and the second semiconductor cladding layer 310 and be received into the photodetector absorption layer 314. Such reception may produce a photocurrent output from the photodetector section. The photocurrent output, or another measurable electrical parameter, may be used by the SMI sensor 300 as part of estimating a distance to the object 324. One such measurable electrical parameter may be a junction voltage, as measured between the intermediate electrodes 313a-b and the base electrode 319.

The SMI sensor 300 may be configured to use self-mixing interference between the primary light emission 320 and received reflections 322 from the object 324 of the primary light emission 320. When the received reflections 322 enter the lasing cavity of the active region 306, the frequency, or another property, of the primary light emission 320 may be varied from the case of no received reflections. The change in the frequency also then in the secondary light emission that is received in the photodetector absorption layer 314. The alteration in the secondary light emission may alter the photocurrent or another electrical parameter in the reverse-biased photodetector section of the SMI sensor 300, allowing for estimation of the distance to the object 324.

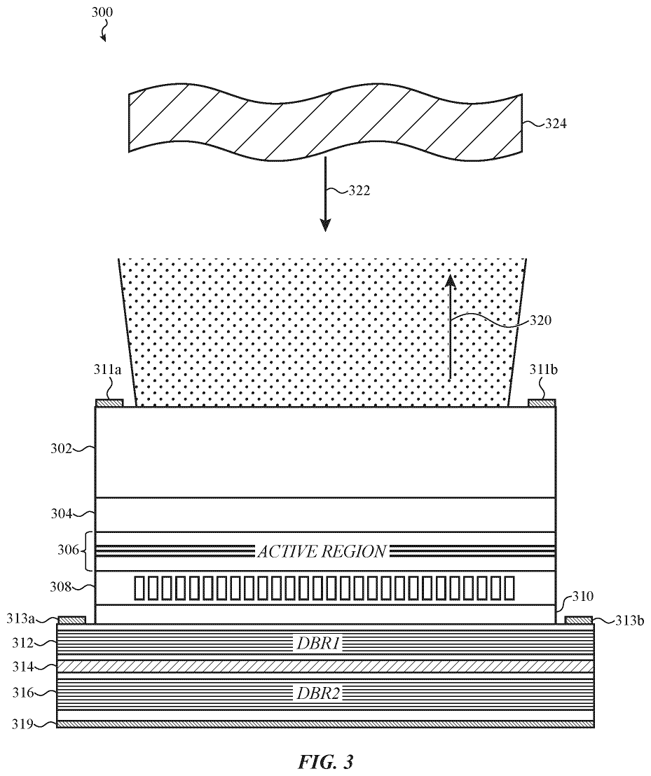

FIG. 4 is a cross-sectional view of a second embodiment of a SMI sensor 400. The SMI sensor 400 includes at least a PCSEL section (or just “PCSEL”) and an associated photodetector separated from the PCSEL by a space or gap. The SMI sensor 400 includes the substrate 402 onto which components of the PCSEL are formed in layers. The substrate 402 may be a semiconductor substrate layer formed with a semiconductor such as Si, GaAs, InP, or another III-V semiconductor. The components of the PCSEL of the SMI sensor 400 include the first semiconductor cladding layer 404, the active region 406, the photonic crystal layer 408, and the second semiconductor cladding layer 410.

The substrate 402, the first semiconductor cladding layer 404, the active region 406, the photonic crystal layer 408, and the second semiconductor cladding layer 410 may be as described for the analogous, respective components of the SMI sensor 300 of FIG. 3, so for brevity those descriptions will not be repeated. The PCSEL section of the SMI sensor 400 also includes a DBR 412 joined to the side of the second semiconductor cladding layer 410 opposite from the photonic crystal layer 408.

The first semiconductor cladding layer 404, the active region 406, the photonic crystal layer 408, the second semiconductor cladding layer 410, and the DBR 412 may be sequentially formed on the substrate 402 by any of various semiconductor fabrication techniques, such as epitaxial deposition.

The SMI sensor 400 may have one or more top electrodes 411a-b formed on the primary light emission side of the substrate 402, the primary light emission side being the side of the substrate 402 through which a primary light emission 420 is emitted. In the orientation of FIG. 4, the primary light emission side is the top of substrate 402. Though shown as two sections, the top electrodes 411a-b may be connected, such as shown for the first electrode 202 of FIG. 2A. The DBR 412 has one or more base electrodes 413 on the side opposite the second semiconductor cladding layer 410.

The photodetector section of the SMI sensor 400 includes an external photodetector 414 (or just “photodetector”) separated from the PCSEL section. The photodetector 414 includes one or more connector electrodes 417 on a first side that faces the DBR 412, with the connector electrodes 417 electrically connected to the one or more base electrodes 413 on the DBR 412. The photodetector 414 also includes one or more bottom electrodes 419 on the side of the photodetector 414 opposite to the first side. The PCSEL section of the SMI sensor 400 and the photodetector section of the SMI sensor 400 may be formed on separate semiconductor chips and subsequently joined or linked.

As the external photodetector 414 is separated from the PCSEL section of the SMI sensor 400, the external photodetector 414 may implemented in various photodetector technologies. In one family of embodiments, the external photodetector 414 may be structured as an active region between a pair of DBRs, as in the case of the photodetector section of the SMI sensor 300 of FIG. 3. In other families of embodiments, the external photodetector 414 may be implemented with a CMOS photodetector structure. Other technologies for the external photodetector 414 may be used. For detection of self-mixing interference in the PCSEL section of the SMI sensor 400, the external photodetector 414 may be chosen to be able to detect changes in electromagnetic properties of its received light, such as frequency or amplitude.

The SMI sensor 400 is configured to detect self-mixing interference of a primary light emission 420 with reflections 422 thereof from the object 424. In some embodiments, the substrate 402 and the first semiconductor cladding layer 404 have n-type doping, and the DBR 412 has p-type doping to form a diode structure that is forward biased when a higher voltage is applied to the base electrodes 413 relative to a lower voltage applied to the top electrodes 411a-b. Under such forward bias, charge carriers are injected into active region and lasing may then occur. The DBR 412 may function as a mirror for the lasing cavity.

As described above, self-mixing interference in the active region 406 of the primary light emission 420 with reflections 422 from the object 424 may induce one or more changes in electromagnetic properties of the generated and emitted laser light, such as frequency or amplitude. The SMI sensor 400 also emits a secondary light emission 426 having those changes through the second semiconductor cladding layer 410 and the DBR 412 toward the photodetector 414.

Though shown in FIG. 4 as being emitted from the edges of the DBR 412, the secondary light emission 426 may emitted from a central location on the DBR 412, which may have the base electrode situated on the edges, similar to the positioning of the first electrode 202 of the embodiment in FIG. 2A. The photodetector 414 may also have its corresponding connector electrodes 417 similarly situated on its surface edges.

When the PCSEL section of the SMI sensor 400 has a forward bias applied between base electrodes 413 and the top electrodes 411a-b so that lasing is induced, the voltage applied between the connector electrodes 417 and the bottom electrodes 419 is such that the photodetector 414 may detect the secondary light emission 426. In the embodiments in which the photodetector 414 is structured as an active region between a pair of DBRs of alternating doping types, a reverse bias is applied so that the photodetector 414 may operate as a resonant cavity photodetector.

In additional and/or alternative embodiments, the SMI sensor 300 and the SMI sensor 400 may further include a second DBR positioned on the light emitting side of the respective substrates 302 and 402. The second DBR may include fewer alternating layers than the DBR 412, and may provide a greater primary emission side surface reflectivity for the PCSEL structure. Such a second DBR may allow for adjustment of the feedback coefficient to improve signal to noise ratio.

Though not explicitly shown in FIGS. 3-4, one skilled in the art will recognize that both the SMI sensor 300 and the SMI sensor 400 may each include additional electronic circuitry such as one or more: voltage or current sources, ground connections, amplifiers, transistors, bypass diodes, or other components. Other types of components that may be included are on-chip lenses, protective layers, among others.

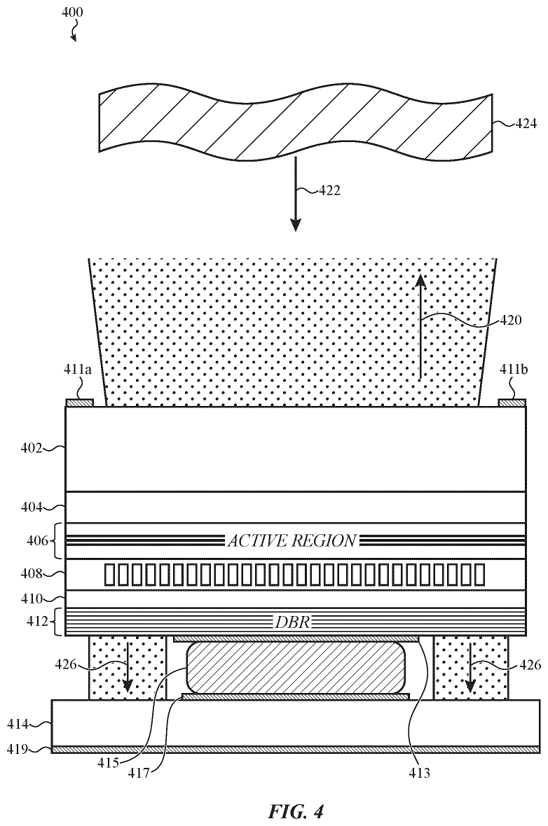

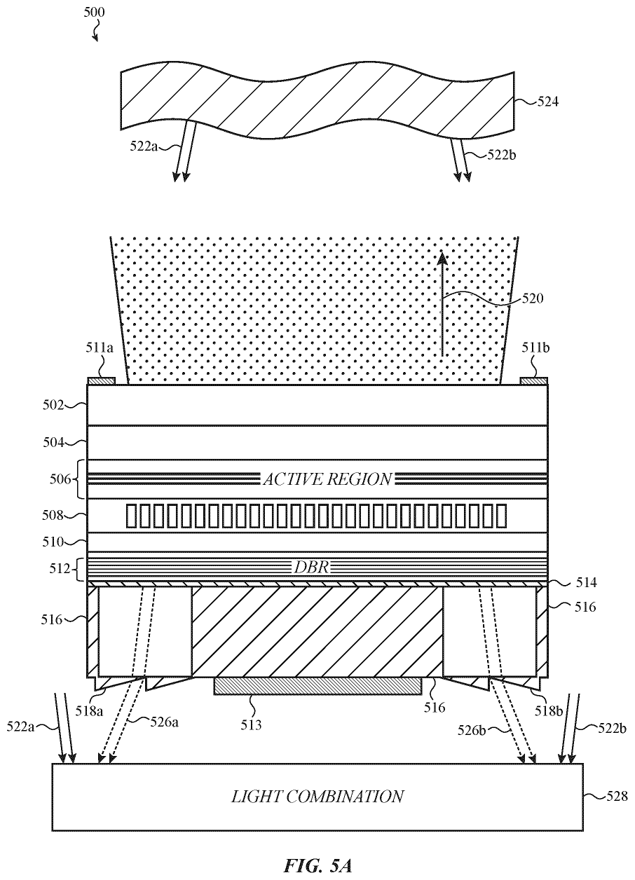

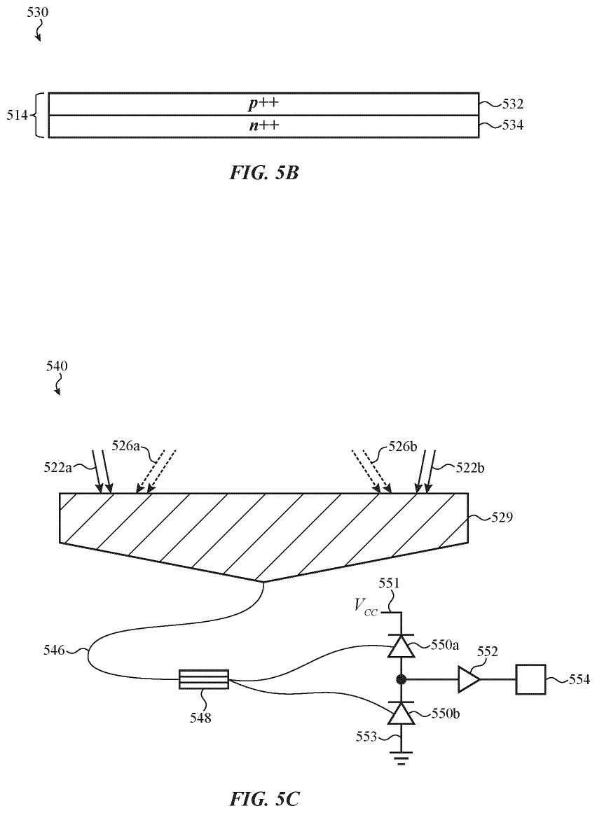

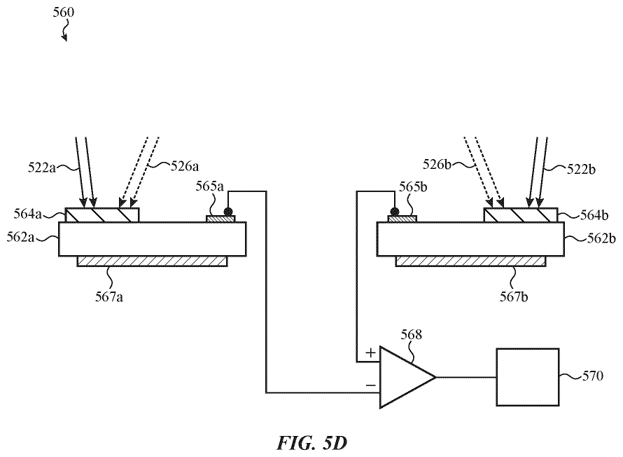

FIG. 5A shows a cross-sectional view of an embodiment of an FMCW sensor 500 that makes use of FMCW measurements to detect information (distance, motion, etc.) regarding an object 524 in an exterior environment. The FMCW sensor 500 emits both a primary light emission 520 toward the object and a secondary light emission 526a-b toward a light combination unit (or “light beam combiner”) 528. Reflections 522a-b of the primary light emission 520 from the object 524 are combined with the secondary light emission 526a-b to generate a net frequency modulated light. In cases that the frequency of the primary light emission 520 is varied in a known way by the FMCW sensor 500, information regarding the distance and motion to the object 524 may be estimated from the net frequency modulated light. PCSEL structures may emit laser light with a narrower laser linewidth than other types of laser diodes (such as VCSEL, or EEL). This may allow the FMCW sensor 500 to be able to sense the object 524 at longer distance.

The FMCW sensor 500 includes a semiconductor current distribution layer 502 with a light emitting side through which a primary light emission 520 is emitted toward an object 524. In the configuration shown in FIG. 5, the light emitting side is at the top of the semiconductor current distribution layer 502. In the FMCW sensor 500, the semiconductor current distribution layer 502 forms the top layer of a PCSEL structure. Following sequentially away from the semiconductor current distribution layer 502, the PCSEL includes as components: a first semiconductor cladding layer 504 joined to the side of the semiconductor current distribution layer 502 opposite the light emitting side, an active region 506, a photonic crystal layer 508, and a second semiconductor cladding layer 510. These components of the PCSEL may be as described above in relation to FIGS. 2A-4. These components are sequentially formed so that the active region is positioned between the first semiconductor cladding layer 504 and the photonic crystal layer 508, and the photonic crystal layer 508 is positioned between the active region 506 and the second semiconductor cladding layer 510.

The FMCW sensor 500 further includes a DBR 512 on the side of the second semiconductor cladding layer 510 opposite the photonic crystal layer 508. The FMCW sensor 500 may also include a tunnel junction 514, as described below in relation to FIG. 5B, formed on a side of the DBR 512 opposite the second semiconductor cladding layer 510. In the embodiment shown in FIG. 5, the FMCW includes a semi-conducting substrate layer 516 on the side of the tunnel junction opposite the DBR 512. The semi-conducting substrate layer 516 may be Si, GaAs, InP, or another III-V semiconductor.

The semiconductor current distribution layer 502, first semiconductor cladding layer 504, active region 506, photonic crystal layer 508, the second semiconductor cladding layer 510, the DBR 512, tunnel junction 514 and semi-conducting substrate layer 516 may be formed on a single semiconductor wafer, such as by epitaxially or vapor deposition, ion implantation, or other technologies.

In some embodiments of the FMCW sensor 500, the semiconductor current distribution layer 502 and the first semiconductor cladding layer 504 are n-type doped. In these embodiments the second semiconductor cladding layer 510 is p-type doped. FIG. 5B shows a cross-section 530 of the tunnel junction 514 for these embodiments. The tunnel junction 514 includes the first tunnel junction layer 532, which is joined to the side of the DBR 512 opposite to the second semiconductor cladding layer 510. The first tunnel junction layer 532 has p-type doping, which may be heavily (with dopant concentration greater than 5×10¹⁸ cm⁻³) p-type doped (p++). The second tunnel junction layer 534 has n-type doping, which may be heavily n-type doped (n++). In embodiments that include the tunnel junction 514, the semi-conducting substrate layer 516 has n-type doping.

In an alternative embodiments, the tunnel junction 514 may not be included, in which case the semi-conducting substrate layer 516 has p-type doping.

One or more electrodes 511a-b are formed on the light emitting side of the semiconductor current distribution layer 502. The electrodes 511a-b may be a single metal loop (rectangular, circular, etc.,) around the edge of the light emitting side of the semiconductor current distribution layer 502, analogous to the first electrode 202 shown in FIG. 2A. One or more other electrodes 513 may be formed on the side of the semi-conducting substrate layer 516 opposite the tunnel junction 514. When a higher voltage is applied at the electrode 513 than a voltage applied at the electrodes 511a-b, a forward bias occurs in the PCSEL structure of the FMCW sensor 500, so that lasing may occur, causing the emission of the primary light emission 520 toward the object 524. Also, a secondary light emission 526a-b may also be emitted through the semi-conducting substrate layer 516. The semi-conducting substrate layer 516 may include one or more on-chip lenses 518a-b that direct the secondary light emission 526a-b toward a light beam combiner 528. The light beam combiner 528 may be separated from the semi-conducting substrate layer 516 by a space or gap.

The primary light emission 520 may impinge on the object 524 and produce reflections 522a-b, The reflections 522 may then be received in the light beam combiner 528 but not in the PCSEL section of the FMCW sensor 500. The secondary light emission 526a-b may function as a local oscillator for FM sensing.

FIG. 5C shows a configuration 540 of components of the light beam combiner 528. The secondary light emission 526a-b and the reflections 522a-b from the object 524 of the primary light emission 520 are received in a particular light beam combiner 529 to produce a combined beam that is input into a waveguide 546. The waveguide 546 may be a fiber optic waveguide. A beam splitter 548 then splits the combined beam equally and sends the two separated beams to a pair of balanced photodetectors 550a and 550b, which may operate as diodes supplied by a high voltage 551 and ground voltage 553. An amplifier 552, which may be a transimpedance amplifier, to amplify the detected FMCW signal. The output of the amplifier 552 is received by processing elements 554, either within the FMCW sensor 500 or in the electronic device containing the FMCW sensor 500.

FIG. 5D shows a cross-sectional view of another embodiment 560 of the light beam combiner 528. The embodiment 560 includes two photosensors 562a and 562b. The two photosensors 562a and 562b may both or separately be implemented as resonant cavity photodiodes (RCPDs), or CMOS photodetectors, or another photodetector technology. The two photosensors 562a and 562b are respectively supplied through the top electrodes 565a and 565b, and bottom electrodes 567a and 567b.

The two photosensors 562a and 562b each are connected with respective metasurfaces 564a and 564b. The metasurface 564a functions to combine the incident reflections 522 and the secondary light emission 526a, which may have different incident angles on the metasurface 546a, into a combined beam that is received by the photosensor 562a. The metasurface 564b functions to combine the incident reflections 522 and the secondary light emission 526b, which may have different incident angles on the metasurface 546b, into a combined beam that is received by the photosensor 562b.

An amplifier 568, such as a transimpedance amplifier, may take as differential inputs photocurrents, or another pair of electrical outputs, produced at the top electrodes 565a and 565b from the two photosensors 562a and 562b. The output of the amplifier 568 is received at the processor or processing unit 570, which may be included in the embodiment 560 of the light beam combiner 528, or a component of an electronic device that includes the FMCW sensor 500.

One skilled in the art will recognize that the individually described SMI sensor 300, the SMI sensor 400 and the FMCW sensor 500 may be part of a respective array of such sensors. The PCSEL structures of the SMI sensor 300, the SMI sensor 400 and the FMCW sensor 500 shown in respective cross-sections of FIGS. 3-5 may be formed on a single chip as part of an array of such PCSEL structures. Also, the RCPD structure of the PD section of the SMI sensor 300 of FIG. 3 may also be formed on the single chip containing the array of PCSELs described in relation to FIG. 3. Multiple copies of the PD structure of SMI sensor 400 may be formed a separate single chip and disposed toward an array of PCSELs as described in relation to FIG. 4. Similarly, multiple copies of the PD structures, or of the light beam combiner, of the FMCW sensor 500 may be formed a separate single chip and disposed toward an array of PCSELs as described in relation to FIG. 5.

Though not explicitly shown in FIG. 5 one skilled in the art will recognize that the FMCW sensor 500 may include additional electronic circuitry, such as one or more: voltage or current sources, ground connections, amplifiers, transistors, bypass diodes, or other components. Other types of components that may be included are on-chip lenses, protective layers, among others.

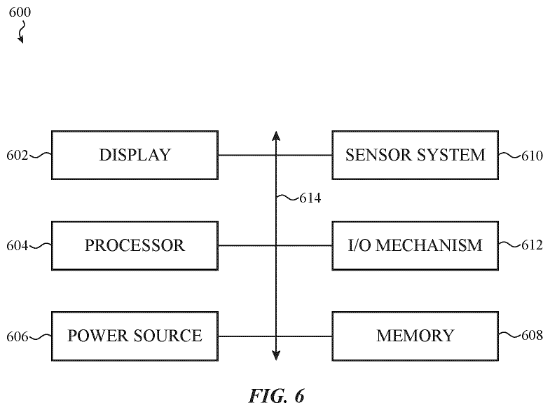

FIG. 6 shows a sample electrical block diagram of an electronic device 600 that includes a PCSEL-based SMI or FMCW sensor, such as any of the PCSEL-based SMI sensors described with reference to any of FIGS. 1A-5D. The electronic device 600 may be an image sensor, depth sensor or another type of sensor. The electronic device 600 may take forms such as a hand-held or portable device (e.g., a smartphone, tablet computer, or electronic watch), a navigation system of a vehicle, and so on. The electronic device 600 may include an optional display 602 (e.g., a light-emitting display), a processor 604, a power source 606, a memory 608 or storage device, a sensor system 610, and an optional input/output (I/O) mechanism 612 (e.g., an input/output device and/or input/output port). The processor 604 may control some or all of the operations of the electronic device 600. The processor 604 may communicate, either directly or indirectly, with substantially all of the components of the electronic device 600. For example, a system bus or other communication mechanism 614 may provide communication between the processor 604, the power source 606, the memory 608, the sensor system 610, and/or the input/output mechanism 612.

The processor 604 may be implemented as any electronic device capable of processing, receiving, or transmitting data or instructions. For example, the processor 604 may be a microprocessor, a central processing unit (CPU), an application-specific integrated circuit (ASIC), a digital signal processor (DSP), a controller, or any combination of such devices. As described herein, the term “processor” is meant to encompass a single processor or processing unit, multiple processors, multiple processing units, or another suitably configured computing element or elements.

In some embodiments, the components of the electronic device 600 may be controlled by multiple processors. For example, select components of the electronic device 600 may be controlled by a first processor and other components of the electronic device 600 may be controlled by a second processor, where the first and second processors may or may not be in communication with each other.

The power source 606 may be implemented with any device capable of providing energy to the electronic device 600. For example, the power source 606 may include one or more disposable or rechargeable batteries. Additionally or alternatively, the power source 606 may include a power connector or power cord that connects the electronic device 600 to another power source, such as a wall outlet.

The memory 608 may store electronic data that may be used by the electronic device 600. For example, the memory 608 may store electrical data or content such as, for example, audio and video files, documents and applications, device settings and user preferences, timing signals, control signals, data structures or databases, image data, maps, or focus settings. The memory 608 may be configured as any type of memory. By way of example only, the memory 608 may be implemented as random access memory, read-only memory, Flash memory, removable memory, other types of storage elements, or combinations of such devices.

The electronic device 600 may also include one or more sensors defining the sensor system 610, such as any of the PCSEL-based sensors described in relation to FIGS. 1A-5D, as well as other types of sensors. The sensors may be positioned substantially anywhere on the electronic device 600. The sensor(s) may be configured to sense substantially any type of characteristic, such as but not limited to, touch, force, pressure, electromagnetic radiation (e.g., light), heat, movement, relative motion, biometric data, distance, and so on. For example, the sensor system 610 may include a touch sensor, a force sensor, a heat sensor, a position sensor, a light or optical sensor, an accelerometer, a pressure sensor (e.g., a pressure transducer), a gyroscope, a magnetometer, a health monitoring sensor, an image sensor, a SPAD-based photon detector, and so on. Additionally, the one or more sensors may utilize any suitable sensing technology, including, but not limited to, capacitive, ultrasonic, resistive, optical, ultrasound, piezoelectric, and thermal sensing technology.

The I/O mechanism 612 may transmit and/or receive data from a user or another electronic device. An I/O device may include a display, a touch sensing input surface such as a track pad, one or more buttons (e.g., a graphical user interface “home” button, or one of the buttons described herein), one or more cameras (including one or more 2D or 3D image sensors, such as any of the PCSEL-based sensors described above in relation to FIGS. 1A-5D, and/or one or more SPAD-based photon detectors), one or more microphones or speakers, one or more ports such as a microphone port, and/or a keyboard. Additionally or alternatively, an I/O device or port may transmit electronic signals via a communications network, such as a wireless and/or wired network connection. Examples of wireless and wired network connections include, but are not limited to, cellular, Wi-Fi, Bluetooth, IR, and Ethernet connections. The I/O mechanism 612 may also provide feedback (e.g., a haptic output) to a user.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. A self-mixing interferometry (SMI) sensor, comprising:
a substrate;
a photonic crystal surface-emitting laser diode disposed on the substrate and configured to make a primary light emission through the substrate, the photonic crystal surface-emitting laser diode comprising:
a photonic crystal layer;
an active region disposed between the photonic crystal layer and the substrate, having a primary emission side through which the primary light emission occurs;
a first semiconductor cladding layer disposed on the primary emission side of the active region and disposed between the active region and the substrate; and
a second semiconductor cladding layer disposed on a secondary light emission side of the active region, the secondary light emission side opposite from the primary emission side, the photonic crystal layer disposed between the second semiconductor cladding layer and the active region;
a distributed Bragg reflector (DBR) disposed on the second semiconductor cladding layer such that the second semiconductor cladding layer is disposed between the DBR and the photonic crystal layer; and
a photodetector positioned proximate to the DBR and configured to receive a secondary light emission emitted from the photonic crystal surface-emitting laser diode through the second semiconductor cladding layer and the DBR, the photodetector configured to produce a measurable electrical parameter related to self-mixing of light within the photonic crystal surface-emitting laser diode.

2. The SMI sensor of claim 1, wherein the photonic crystal layer defines a patterned photonic crystal structure.

3. The SMI sensor of claim 1, wherein:
the DBR is a first DBR; and
the photodetector comprises:
a photodetector absorption layer adjacent to the first DBR and opposite to the second semiconductor cladding layer; and
a second DBR adjacent to the photodetector absorption layer and opposite to the first DBR.

4. The SMI sensor of claim 3, wherein:
the photonic crystal surface-emitting laser diode and the photodetector comprise epitaxial layers on the substrate; and
the measurable electrical parameter related to the self-mixing is a photocurrent of the photodetector.

5. The SMI sensor of claim 3, wherein:
the substrate comprises a semiconductor doped to be n-type; and
the semiconductor of the substrate comprises one of gallium arsenide (GaAs) or indium phosphide (InP).

6. The SMI sensor of claim 3, wherein:
the first DBR has n-type doping and the second DBR has p-type doping;
the photodetector absorption layer is joined to the first DBR; and
at least during the secondary light emission from the photonic crystal surface-emitting laser diode, the first DBR is biased with a first voltage higher than a second voltage applied to the second DBR.

7. The SMI sensor of claim 1, wherein:
the photodetector is spaced apart from the DBR; and
the photodetector is electrically connected to the DBR by metallic links between at least a first electrode on the DBR and at least a second electrode on the photodetector.

8. The SMI sensor of claim 7, wherein:
the substrate comprises a semiconductor doped to be n-type;
the semiconductor comprises one of gallium arsenide (GaAs), indium phosphide (InP), indium gallium arsenide (InGaAs), aluminum gallium arsenide (AlGaAs), or indium gallium arsenide phosphorus (InGaAsP);
the photonic crystal surface-emitting laser diode and the DBR comprise epitaxial layers on the substrate; and
the measurable electrical parameter related to the self-mixing is a photocurrent of the photodetector.

9. The SMI sensor of claim 1, further comprising an additional DBR adjacent to the substrate opposite to the first semiconductor cladding layer, the additional DBR having fewer alternating layers than the DBR.

10. A frequency modulated, continuous wave (FMCW) sensor, comprising:
a semiconductor current distribution layer;
a photonic crystal surface-emitting laser diode disposed on the semiconductor current distribution layer and configured to make a primary light emission through the semiconductor current distribution layer, the photonic crystal surface-emitting laser diode comprising:
a photonic crystal layer;
an active region disposed between the photonic crystal layer and the semiconductor current distribution layer, having a primary emission side through which the primary light emission occurs;
a first semiconductor cladding layer disposed on the primary emission side of the active region and disposed between the active region and the semiconductor current distribution layer; and
a second semiconductor cladding layer disposed on a secondary light emission side of the active region, the secondary light emission side opposite from the primary emission side, the photonic crystal layer disposed between the second semiconductor cladding layer and the active region;
a distributed Bragg reflector (DBR) disposed on the second semiconductor cladding layer such that the second semiconductor cladding layer is disposed between the DBR and the photonic crystal layer;
a semiconductor substrate layer adjacent to the DBR opposite to the second semiconductor cladding layer;
a light beam combiner positioned across a gap from the semiconductor substrate layer of the photonic crystal surface-emitting laser diode and configured to produce an FMCW optical output by combining a reflection of the primary light emission emitted from the primary emission side of the active region and a secondary light emission emitted from the secondary light emission side of the active region, the secondary light emission emitted through the semiconductor substrate layer; and
an optoelectronic circuit configured to receive the FMCW optical output and produce a measurable electrical parameter related to a modulation of the FMCW optical output.

11. The FMCW sensor of claim 10, wherein:
the semiconductor current distribution layer has n-type doping;
the first semiconductor cladding layer has n-type doping;
the second semiconductor cladding layer has p-type doping;
the DBR has p-type doping; and
the semiconductor substrate layer has n-type doping and is one of gallium arsenide (GaAs), indium phosphide (InP), indium gallium arsenide (InGaAs), aluminum gallium arsenide (AlGaAs), or indium gallium arsenide phosphorus (InGaAsP);

12. The FMCW sensor of claim 11, further comprising a tunnel junction disposed between the DBR and the semiconductor substrate layer; wherein the tunnel junction includes:
a heavily p-type doped layer adjacent to the DBR; and
a heavily n-type doped layer adjacent to the p-type doped layer opposite the DBR.

13. The FMCW sensor of claim 11, wherein the photonic crystal surface-emitting laser diode further comprises at least one on-chip lens positioned on the semiconductor substrate layer and configured to direct the secondary light emission to the light beam combiner.

14. The FMCW sensor of claim 11, wherein:
the light beam combiner includes:
a first metasurface configured to combine the reflection of the primary light emission with secondary light emission and produce a first combined output light; and
a second metasurface configured to combine the reflection of the primary light emission with secondary light emission and produce a second combined output light; and
the optoelectronic circuit comprises:
a first photodetector positioned to receive the first combined output light; and
a second photodetector positioned to receive the second combined output light; and
an amplifier configured to receive both an electrical output of the first photodetector and an electrical output of the second photodetector.

15. The FMCW sensor of claim 14, wherein the first and second photodetectors are balanced photodetectors.

16. The FMCW sensor of claim 14, wherein the electrical output of the first photodetector and the electrical output of the second photodetector are photocurrents.

17. An electronic device, comprising:
an array of photonic crystal surface-emitting laser diodes, each photonic crystal surface-emitting laser diode operable to emit a primary light emission from the photonic crystal surface-emitting laser diodes through a light emission surface of the electronic device toward one or more objects exterior to the electronic device;
an array of photodetectors configured to receive at least a secondary light emission emitted from the photonic crystal surface-emitting laser diodes of the array of photonic crystal surface-emitting laser diodes toward the array of photodetectors; and
electronic circuitry configured to receive measurable output signals from photodetectors of the array of photodetectors; wherein:
each photonic crystal surface-emitting laser diode of the array of photonic crystal surface-emitting laser diodes comprises:
an n-doped current distribution layer proximate to the light emission surface of the electronic device through which the primary light emission is emitted from the electronic device;
an n-type cladding layer adjacent to the n-doped current distribution layer and opposite to the light emission surface of the electronic device;
an active region adjacent to the n-type cladding layer and opposite to the semiconductor substrate layer;
a photonic crystal layer adjacent to the active region and opposite to the n-type cladding layer;
a p-type cladding layer adjacent to the photonic crystal layer and opposite to the active region; and
a p-type distributed Bragg reflector (DBR) layer adjacent to the p-type cladding layer and opposite to the photonic crystal layer.

18. The electronic device of claim 17, wherein:
the photonic crystal surface-emitting laser diodes of the array of photonic crystal s surface-emitting laser diodes are individually addressable by the electronic circuitry; and
the electronic circuitry is operable to produce a depth map of the one or more objects exterior to the electronic device using the measurable output signals from the photodetectors of the array of photodetectors.

19. The electronic device of claim 18, wherein:
the photodetectors of the array of photodetectors include a photodetector absorption layer;
the photodetectors of the array of photodetectors produce output signals related to self-mixing interference of the secondary light emission with reflections of the primary light emission from the one or more objects exterior to the electronic device; and
the output signals related to the self-mixing interference are included in the measurable output signals used by the electronic device to produce the depth map.

20. The electronic device of claim 18, wherein:
the photodetectors of the array of photodetectors include a pair of separate and balanced semiconductor photodetectors with respective metasurfaces;
the metasurfaces are configured to combine the secondary light emission with reflections of the primary light emission from the one or more objects exterior to the electronic device; and
the pair of separated and balanced semiconductor photodetectors produce respective output photocurrents related to frequency modulation between the combined primary light emission and the secondary light emission.
